(19) United States
(12) Patent Application Publication
(10) Pub. No.: US 2018/0223436 A1
(43) Pub. Date: Aug. 9, 2018

(54) CUTTING TOOL COMPRISING A MULTIPLE-PLY PVD COATING

(71) Applicant: WALTER AG, Tubingen (DE)

(72) Inventor: Veit SCHIER, Echterdingen (DE)

(21) Appl. No.: 15/524,551

(22) PCT Filed: Oct. 20, 2015
(86) PCT No.: PCT/EP2015/074277

§ 371 Date: May 4, 2017

(30) Foreign Application Priority Data
Nov. 5, 2014 (EP) 14191910.0

(51) Int. Cl. C23C 28/04; C23C 14/32; C23C 14/34; C23C 14/35; C23C 14/02; C23C 28/00; C23C 14/06

(52) U.S. Cl. CPC C23C 28/044; C23C 14/325; C23C 14/3485; C23C 14/35; C23C 14/0641; C23C 28/048; C23C 28/44; C23C 28/42; C23C 14/024

(57) ABSTRACT

A tool includes a substrate of hard metal, cermet, ceramic, steel or high speed steel, and a multiple-ply coating. The multiple-ply coating includes a connecting layer and a wear-resistant layer deposited directly onto the connecting layer. The connecting layer has a multiple-ply design. Plies of the connecting layer, which lie one immediately over the other, have different compositions formed from carbides, nitrides, oxides, carbonitrides, oxycarbides, carboxy nitrides of at least two different metals selected from Ti, V, Cr, Zr, Nb, Mo, Ru, Hf, Ta, W, Al, Si, Y, Li and B, and solid solutions thereof. The wear-resistant layer has a single or multiple-ply design. Each of the plies of the wear-resistant layer are formed from carbides, nitrides, oxides, carbonitrides, oxycarbides, carboxy nitrides of at least two different metals selected from Ti, V, Cr, Zr, Nb, Mo, Ru, Hf, Ta, W, Al, Si, Y, Li and B and solid solutions thereof.

### SUBJECT-MATTER OF THE INVENTION

The present invention relates to a tool comprising a substrate of hard metal cermet, ceramic, steel or high-speed steel and a multi-layer coating applied thereto in a PVD process, having an overall thickness of 1 μm to 20 μm, wherein the multi-layer coating comprises a bonding layer deposited by means of a cathodic vacuum arc evaporation (arc PVD) and an anti-wear protective layer deposited thereon by means of high power impulse magnetron sputtering (HIPIMS). The invention further relates to a process for the production of such a tool.

### BACKGROUND OF THE INVENTION

Cutting tools such as those used for example for chip removing metal machining in general consist of a substrate (base body) of hard metal, cermet, steel or high-speed steel having a wear-resistant single-layer or multi-layer coating of metallic hard material layers deposited thereon by means of a CVD process (chemical vapor deposition) or a PVD process (physical vapor deposition). In PVD processes, a distinction is made between different variants, such as for example cathode sputtering (sputter deposition), cathodic vacuum arc evaporation (arc PVD), ion plating, electron beam evaporation and laser ablation. Cathode sputtering such as magnetron sputtering, reactive magnetron sputtering and high power impulse magnetron sputtering (HIPIMS) and the arc evaporation belong to the PVD processes most frequently used for the coating of cutting tools.

Performing cathodic vacuum arc evaporation (arc PVD) an arc melting and evaporating the target material is burning between the chamber and the target. In the process, a big part of the evaporated material is ionized and accelerated towards the substrate, the substrate having a negative potential (bias potential), and is deposited on the substrate surface. The cathode vacuum arc evaporation (arc PVD) is characterized by a high rate of deposition, by dense layer structures due to the high ionization of the evaporated material, as well as by process stability. A substantial disadvantage, however, is the process-dependent deposition of micro particles (droplets) caused by the emission of small metal splashes, the avoidance of which is extremely complex. The droplets lead to an undesirably high surface roughness on the deposited layers.

In the cathode sputtering (sputtering) atoms or molecules are removed from the target by bombardment with high-energy ions and are transferred into the gas phase from which they are subsequently deposited on the substrate, either directly or after reaction with a reaction gas. The cathode sputtering being supported by magnetron comprises two essential process variants, the conventional DC magnetron sputtering (DC-MS) and the HIPIMS process. In the magnetron sputtering, the unfavorable formation of droplets in the cathodic vacuum arc evaporation (arc PVD) does not occur. In the conventional DC-MS the coating rates are, however, comparatively low, implying higher process durations and thus an economic disadvantage.

When using high power impulse magnetron sputtering (HIPIMS) the magnetron is operated in the pulsed mode at high current densities, resulting in an improved layer structure in the form of denser layers, in particular due to an improved ionization of the sputtered material. In the HIPIMS the current densities at the target typically exceed that of the conventional DC-MS.

Layers deposited by means of DC-MS and HIPIMS often exhibit considerable structural differences. DC-MS layers usually grow in a columnar structure on the substrate. In contrast, in the HIPIMS process microcrystalline layer structures are obtained, being characterized by an improved wear behavior and longer service lives associated therewith in comparison to DC-MS layers. HIPIMS layers are usually harder than the columnar DC-MS layers, but they also show disadvantages with respect to their adhesion to many substrates.

EP 2 653 583 describes a coating procedure for depositing a layer system, consisting essentially of three layers, by means of PVD, wherein the layer system comprises arranged one over the other a contact layer S1 deposited by means of cathodic vacuum arc evaporation (arc PVD) from an evaporation material (target) M1, a covering layer S3 deposited by means of HIPIMS from a discharge material (target) M2 and an intermediate layer S2 deposited in between by parallel operation of arc PVD and HIPIMS of the evaporating material M1 as well as of the discharge material M2. In this layer system, it is intended to obtain a lower surface roughness compared to comparative coatings having in principle the same chemical composition.

WO2013/068080 describes a process for the production of a layer system by means of HIPIMS wherein HIPIMS layers having alternately finer and coarser granularity are deposited by alternating application of longer and shorter pulse durations. Such an alternating layer system should have good wear characteristics.

### Object

The object of the present invention was providing a tool with an anti-wear protective coating as well as a process for its production, having the advantages of known layer systems, in particular the advantages of layers deposited in the HIPIMS process, and at the same time overcoming the disadvantages known from the prior art, in particular inadequate adhesion.

### DESCRIPTION OF THE INVENTION

This object is achieved according to the invention by providing a tool with a substrate of hard metal, cermet, ceramic, steel or high-speed steel and a multi-layer coating deposited thereto in the PVD process, having an overall thickness of 1 μm to 20 μm, wherein the multi-layer coating comprises a contact layer and an anti-wear protective layer deposited directly on top of it,
wherein the bonding layer is deposited by means of cathodic vacuum arc vapor deposition (arc PVD) and has a multi-layer design, wherein layers of the bonding layer which are arranged directly one over the other have different compositions, and wherein the multiple layers of the bonding layer are each formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof, and
wherein the anti-wear protective layer is deposited by means of high-power impulse magnetron sputtering (HIPIMS) and has a single-layer or multi-layer design, wherein the one or more layers of the anti-wear protective layer are each formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof.

The anti-wear protective layer deposited by means of a HIPIMS process contributes significantly to the performance of the tool according to the invention, in particular in metal processing machining. Coatings deposited by means of HIPIMS processes are characterized by their fine layer structures and high degree of hardness and high moduli of elasticity (E moduli/Young's moduli) associated therewith. The Vickers hardness of a layer deposited by means of HIPIMS, for example of a TiAlN layer, may for example be in the range of from 3000 to 4500 HV. The E modulus for such layers may be in the range of from 400 to 500 GPa. In contrast, hard metal substrates for example exhibit Vickers hardnesses in the order of from 1300 to 2400 HV. Furthermore, the layers deposited by means of HIPIMS have significantly smoother surfaces than layers deposited by means of arc PVD, having advantages in metal machining, for example with respect to chip removal.

Large differences between the hardnesses at the transition from the substrate to the coating or at the transition from a layer to the next layer arranged directly on top of it decrease the adhesion of the layer to the substrate and lead to a premature detachment of the coating, faster wear and thus shorter service lives of the tools.

The provision of bonding layers for improving the adhesion of an anti-wear protective layer to the substrate is known in general. Frequently, bonding layers possess components of the materials arranged on top and underneath, in order to form a layer which in terms of composition and microstructure is between those of the layers arranged on top and the layers arranged underneath, thereby imparting adhesion.

It has now surprisingly been found that particular advantages may be achieved, in particular with respect to the adhesion of an anti-wear protective layer according to the present invention, being deposited by means of HIPIMS, together with a bonding layer formed according to the invention, being deposited by means of cathode vacuum arc deposition (arc PVD) and having a multi-layer design, wherein the layers arranged directly one over the other show different compositions.

As already stated, an anti-wear protective layer deposited by means of HIPIMS in general shows a considerably higher Vickers hardness than for example a conventional WC—Co hard metal substrate. The large difference in terms of hardness may cause a decreased adhesion of a HIPIMS layer deposited directly on the substrate or another layer having a lower hardness and may cause an earlier detachment of the anti-wear protective layer and faster wear of the tool. The HIPIMS process does not allow the hardness of the deposited anti-wear-protective layer to be arbitrarily adapted to that of the substrate or any other layer arranged underneath in order to reduce this adhesion problem. A reduction in the hardness of the anti-wear protective layer is often not desired, too, since a high hardness of the anti-wear protective layer is advantageous in many metal machining processes.

The anti-wear protective layer deposited in the HIPIMS process may itself be single-layered or multi-layered. A multi-layer HIPIMS anti-wear protective layer may be formed by varying the compositions of the layers and/or varying of the deposition parameters to have a gradient of the hardness within the HIPIMS anti-wear protective layer such that the layer has a similar hardness to the bonding layer in the area of the bonding to the surface of the bonding layer, and the hardness further increases towards the surface of the HIPIMS anti-wear protective layer. HIPIMS anti-wear protective layers having a particular high hardness and nevertheless a superior bonding may be produced in this way. In a particularly preferred embodiment of the invention, therefore, not only the arc PVD bonding layer has a multi-layer design but also the HIPIMS anti-wear protective layer.

In combining the anti-wear protective layer deposited by means of HIPIMS according to the invention with the multi-layer bonding layer according to the invention the disadvantages known from the prior art could surprisingly be overcome, in particular inadequate adhesion of the HIPIMS layer and comparatively long service lives of the tools could be obtained.

In one embodiment of the invention the layers of the bonding layer are each formed from nitrides or carbonitrides of at least two different metals, selected from Ti, Al, Si, and Cr. Layers of AlCrN, AlCrSiN, TiAlN, TiAlSiN, and TiSiN are preferred, wherein TiAlN is quite particularly preferred.

These compositions of the layers of the bonding layer have shown to be particularly advantageous for the improvement of the bonding of the HIPIMS anti-wear protective layer. It is believed that this is due to these hard materials all having a similar face-centered cubic structure, high hardnesses and high E moduli.

The multi-layer bonding layer has at least two layers arranged one over the other having different compositions, wherein in the sense of the present invention layers containing the same elements, for example Ti, Al and N, but having different stoichiometric compositions are also defined as “layers having different compositions”, for example layers arranged one over the other of Ti_{0.33}Al_{0.67}N and Ti_{0.5}Al_{0.5}N. In a preferred embodiment of the invention, the multi-layer bonding layer has at least 4 layers arranged one over the other, preferably at least 10 layers arranged one over the other. Surprisingly, increasing the number of individual layers has been shown to improve the variation and hardness running perpendicularly towards the substrate surface, respectively, and to achieve a less graded grading of the hardness profile within the bonding layer. At the same time the crack resistance of the bonding layer in metal processing application is increased. It is assumed that this is due to the increase in the number of layer boundaries at which fracture energies may be dissipated, thereby more effectively preventing the propagation of the crack. It is further preferred that the bonding layer has at most 300, preferably at most 100, particularly preferably at most 50 layers arranged one over the other. If the number of layers of the bonding layer is too high for a given thickness of the bonding layer which advantageously should be no more than approximately 1 μm, the individual layers become very thin until down to a few atom layers, such that as a consequence the desired layer boundaries are not defined any more, which adversely affects crack resistance.

In a further preferred embodiment of the invention the multi-layer bonding layer is formed such that within the layer the Vickers hardness increases perpendicular to the substrate surface in the direction from the substrate to the anti-wear protective layer and the Vickers hardnesses within the multi-layer bonding layer are in the range of from 1800 HV to 3500 HV, preferably 2000 HV to 3300 HV. The increase in hardness depicts a gradient over the overall thickness of the bonding layer that may run linear, non-linear or graded, as well.

It is advantageous to obtain as small differences as possible between the hardnesses, each, at the transition from the substrate or a layer underneath the bonding layer to the bonding layer on the one hand and at the transition of the bonding layer to the HIPIMS anti-wear protective layer on the other hand. The multi-layer bonding layer according to the invention allows for the adjustment of the hardness values within the layer, which is not possible in a single-layer bonding layer to the extent as in the multi-layer bonding layer.

As a result of the increase in the Vickers hardness within the bonding layer in the direction from the substrate to the anti-wear protective layer according to the invention, a great difference in hardness between the substrate or a layer underneath the bonding layer and the HIPIMS anti-wear protective layer can advantageously be compensated for. Thus, an improved adhesion of the HIPIMS anti-wear protective layer could be achieved and hence improved service lives of the tools.

Changing the coating parameters during the deposition process is one means of varying hardness within the bonding layer, in this case in particular changing the bias potential during the deposition process. Increasing the bias potentials during the deposition in general leads to an increase in the hardness.

However, exclusively changing the bias potential during the deposition of a single-layer bonding layer would in general not be sufficient to provide a hardness gradient within the layer bridging the difference in hardness between a conventional hard metal substrate, having Vickers hardnesses in the range of approximately 1300 to 1400 HV, and those of a layer deposited by means of HIPIMS, for example a TiAlN layer, in the range of approximately 3000 to 4500 HV. By varying the bias potentials a change of the hardness within a single-layer bonding layer of no more than presumably about 200 to 300 HV could be obtained. It is only the combination of modifying the deposition parameters, in particular the bias potential, together with the design of the multi-layer bonding layer according to the invention, which is characterized in that layers of the bonding layer that are arranged directly one over the other have different compositions, that enable the formation of a hardness gradient within the bonding layer over a broad difference in hardness between for example the substrate and the HIPIMS anti-wear protective layer.

In a further preferred embodiment of the invention the multi-layer bonding layer is designed such that within the multi-layer bonding layer the modulus of elasticity (E modulus) increases perpendicular to the substrate surface in the direction from the substrate to the anti-wear protective layer and the values for the modulus of elasticity (E modulus) within the multi-layer bonding layer are in the range of from 380 GPa to 550 GPa, preferably from 420 GPa to 500 GPa.

The multi-layer bonding layer advantageously has a thickness perpendicular to the substrate surface in the range of from 0.01 μm to 1 μm, preferably 0.05 μm to 0.6 μm, particularly preferably 0.1 μm to 0.4 μm. If the bonding layer is too thin, no sufficient coverage of the surface arranged underneath the bonding layer is obtained and thus also no sufficient improvement of the adhesion of the HIPIMS anti-wear protective layer.

The surface roughness of the arc PVD bonding layer increases in general together with its thickness. The deposition of the anti-wear protective layer in the HIPIMS process is intended to provide a smooth surface by at least partially compensating the surface roughness of the arc PVD bonding layer. However, if the bonding layer is too thick, its roughness highly impacts the surface of the entire laminate of arc PVD bonding layer and HIPIMS anti-wear protective layer, resulting in an undesirably high surface roughness of the HIPIMS anti-wear protective layer.

The thickness of the individual layers forming the entire bonding layer, in the case that the individual layers have about the same thicknesses, corresponds to the thickness of the bonding layer divided by the number of individual layers. Typically, the individual layers of the bonding layer have a thickness in the range of from 20 to 200 nm.

The scope of the present invention also encompasses a variation of the thicknesses of the individual layers within the bonding layer. For example, this can be achieved by changing the vaporizer current during the deposition of the multi-layer bonding layer. Thereby an increase of the hardness within the bonding layer can also be obtained. If within the bonding layer the layers arranged one over the other having different compositions also have different hardnesses, an increase of the thicknesses of the individual layers of the harder material and/or a decrease of the thicknesses of the individual layers of the softer material may provide or may contribute to provide a hardness gradient within the bonding layer. Generally, a Ti_{0.5}Al_{0.5}N material deposited from a TiAl (50:50) target will be softer than a Ti_{0.33}Al_{0.67}N material deposited from a TiAl (33:67) target. An increase in the hardness within a TiAlN bonding layer could thus be obtained by increasing the layer thicknesses of the Ti_{0.33}Al_{0.67}N material and/or by reducing the layer thicknesses of the Ti_{0.5}Al_{0.5}N material by accordingly varying the vaporizer currents at the respective targets during the deposition.

The single-layer or multi-layer anti-wear protective layer advantageously has a thickness in the range of from 0.4 μm to 20 μm, preferably 1 μm to 10 μm, particularly preferably 1.5 μm to 5 μm.

In a further embodiment of the invention the ratio of the thickness of the single-layer or multi-layer anti-wear protective layer to the thickness of the multi-layer bonding layer is at least 2.0, preferably at least 2.3, particularly preferably at least 3.5, quite particularly preferably at least 4.0. If the arc PVD bonding layer is too thick in relation to the HIPIMS anti-wear protective layer, the entire layer laminate of arc PVD bonding layer and HIPIMS anti-wear protective layer obtains an undesirably high surface roughness, as explained above.

In a further embodiment of the invention the layers of the multi-layer bonding layer comprise alternating layers of titan-aluminum nitride having different compositions, wherein layers with a ratio of Ti:Al of (30 to 36):(70 to 64) alternate with layers with a ratio of Ti:Al (40 to 60):(60 to 40), preferably of (47 to 53):(53:47). The difference of the content of Al between the layers should advantageously be at least 5 atomic % Al.

The HIPIMS anti-wear protective layer may have a single-layer or a multi-layer design. In a preferred embodiment of the invention, the anti-wear protective coating is multi-layered and has at least 2, 4 or 10 and at most 50, 100 or 300 layers arranged one over the other. As indicated above, a multi-layer HIPIMS anti-wear protective layer may be formed to have a gradient in hardness within the HIPIMS anti-wear protective layer by varying the compositions of the layers and/or the deposition parameters such that the layer in the region of the bonding to the surface of the bonding layer has a hardness similar to the one of the bonding layer and the hardness further increases towards the surface of the HIPIMS anti-wear protective layer. In this way, HIPIMS anti-wear protective layers having a particular high hardness and nevertheless a superior bonding are producible.

The combination of a bonding layer and an anti-wear protective layer according to the invention may form the entire coating of a tool. However, the invention also encompasses tools having provided between the substrate and the bonding layer one or more further hard material layers and/or metal layers, preferably TiN or metallic Ti. Furthermore, one or more further layers may be provided on top of the anti-wear protective layer, preferably one or more decorative layers of TiN, TiCN, ZrN or other hard materials known for decorative layers. Such decorative layers are very thin, in general between 0.2 and 1 μm, and generally apart from having a decorative function also function as an indicator, as a wear of the decorative layer indicates whether and, if applicable, to what extend a tool has already been used. Further layers having a low friction surface may advantageously also be provided, which layers for example enable an improved chip removal in the chipping metal machining, e.g. diamond-like or graphitic carbon layers. Oxides may as well be applied as outermost layers, for example aluminum oxide or aluminum chromium oxide, which can reduce the tribochemical wear.

The invention also encompasses a process for the production of a coated tool comprising the steps of
applying a base body of hard metal, cermet, ceramic, steel or high-speed steel with a multi-layer coating having an overall thickness of 1 μm to 20 μm by means of a PVD process, wherein the multi-layer coating comprises a bonding layer and an anti-wear protective layer deposited directly on top of it,
   wherein the bonding layer is deposited by means of reactive or non-reactive cathodic vacuum arc vapor deposition (arc PVD) to have a multi-layer design, wherein two layers of the bonding layer which are each arranged directly one over the other have different compositions, and wherein the multiple layers of the bonding layer are formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof, and wherein the anti-wear protective layer is deposited by means of high-power impulse magnetron sputtering (HIPIMS) to have a single-layer or multi-layer design, wherein the one or more layers of the anti-wear protective layer are each formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof.

In a preferred embodiment of the process according to the invention, the layers of the bonding layer are each formed from nitrides or carbonitrides of at least two different metals, selected from Ti, Al, Si, and Cr, preferably from AlCrN, AlCrSiN, TiAlN, TiAlSiN, and TiSiN, particularly preferably from TiAlN.

As already explained above, it is advantageous if there are as small differences as possible between the mechanical properties, in particular the hardness (Vickers hardness), at the transition from the substrate or a layer underneath the bonding layer to the bonding layer on the one hand and at the transition from the bonding layer to the HIPIMS anti-wear protective layer on the other hand. By changing the deposition parameters over the course of the deposition of the multi-layer bonding layer, in particular by changing the bias potentials, the hardness within the bonding layer may be varied over a broad range in order to improve the adhesion of the HIPIMS anti-wear protective layer to the bonding layer. In a single-layer bonding layer this would not be possible to the extent of the present invention.

In a preferred embodiment of the process according to the invention, therefore, the deposition parameters for the deposition of the multi-layer bonding layer are varied such that within the multi-layer bonding layer the Vickers hardness perpendicular to the substrate surface in the direction from the substrate to the anti-wear protective layer increases and the Vickers hardnesses within the multi-layer bonding layer are in the range of from 1800 HV to 3500 HV, preferably 2000 HV to 3300 HV, whereby the deposition parameters to be varied during the deposition of the multi-layer bonding layer comprise at least the bias potential.

### EXAMPLES

The coatings according to the invention were produced in a 6-flange PVD installation HTC1000 (Hauzer, Venlo, Netherlands). The substrates were rotated on rotary tables. For the HIPIMS process, a plasma generator by Zpulser LLC, Mansfield, USA, was used. Coat thicknesses and layer thicknesses indicated in the examples as well as hardness values and values for the E modulus were each measured on the flank face of the coated tool.

The pulse sequence applied herein in the HIPIMS process (pulse file 60) comprises the following subsequences:
1. 5×34 μs/6 μs (on/off)
2. 3×24 μs/6 μs (on/off)
3. 4×14 μs/8 μs (on/off)
4. 50×10 μs/12 μs (on/off)

### Example 1

### Substrate:

Hard metal: WC (fine grain)—10 wt. % Co
Vickers hardness: 2000 HV
E modulus: 500 GPa

### Bonding Layer (Multi-Layer):

Process: arc PVD
Targets: (1) TiAl (50:59), 100 mm diameter, reactor position 2
   (2) TiAl (33:67), 100 mm diameter, reactor position 5 (opposite)

### Deposition Parameters

Vaporizer current: 140 A
Center magnet polarity north front
Total pressure: Gradient from 4 to 10 PA N₂ over 3 min
Bias potential: DC, gradient from 40 to 60 V over 3 min

### Anti-Wear Protective Layer (Single-Layer):

Process: HIPIMS
Targets: TiAlN (33:67), 1800×200 mm, reactor positions 3 and 6 (opposite)

### Deposition Parameters

Average power: 12 kW (per target)
Bias potential: DC, 100 V
Peak power: 130 kW
Peak current: 160 A
Frequency: 110 Hz
Pulse file: 60

The values given are average values since the plasma conditions change constantly as the substrate table is moved.

The deposited bonding layer had a total thickness of 0.2 μm and consisted of about 6 TiAlN individual layers having alternately different compositions Ti_{0.5}Al_{0.5}N and Ti_{0.33}Al_{0.67}N (corresponding to the compositions of the targets used). The individual layers of the bonding layer had therefore a thickness of about 33 nm, each. Due to the gradual variation (increase) of the bias potential during the deposition of the layer, the Vickers hardness of the deposited bonding layer increased in a direction from the substrate outwards from 2200 HV at 40 V bias potential to 2900 HV at 60 V bias potential. The E modulus within the bonding layer increased from 450 GPa at 40 V bias potential to 480 GPa at 60 V bias potential. The properties of hardness and E modulus were measured on accordingly produced layers, however, during their deposition the parameters varied herein were kept constant, for example a constant bias potential of 40 V, since measures of Vickers hardness and E modulus are not possible for thin layer regions of only a few nanometers.

The anti-wear protective layer deposited in the HIPIMS process had a total thickness of 2 μm and consisted of Ti_{0.33}Al_{0.67}N (corresponding to the composition of the target used). The Vickers hardness of the anti-wear protective layer was 3300 HV and the E modulus was 480 GPa.

### Example 2

In this example the same substrate as in example 1 was used. For the multi-layer bonding layer at first a Ti_{0.5}Al_{0.5}N layer having a thickness of about 50 nm was deposited in a first step 1 at a bias potential of 70 V and subsequently in a second step 2 a layer sequence having a thickness of about 0.2 μm consisting of about 6 TiAlN individual layers (individual layer thickness about 33 nm) having alternately different compositions Ti_{0.05}Al_{0.5}N and Ti_{0.33}Al_{0.67}N was deposited at a bias potential of 100 V.

### Bonding Layer (Multi-Layer):

Process: arc PVD

### Step 1

Target: TiAl (50:50), 100 mm diameter, reactor position 2

### Deposition Parameters

Vaporizer current: 150 A
Center magnet polarity north front
Total pressure: 4.5 Pa N₂
Bias potential: DC, 70 V

### Step 2

Targets: (1) TiAl (33:67), 100 mm diameter, reactor position 5
   (2) TiAl (50:50), 100 mm diameter, reactor position 2 (opposite)

### Deposition Parameters

Vaporizer current: 140 A
Center magnet polarity north front
Total pressure: Gradient from 4 to 10 Pa N₂ over 3 min
Bias potential: DC, 100 V

### Anti-Wear Protective Layer (Multi-Layer):

Process: HIPIMS
Targets: (1) TiAl (33:67), 1800×200 mm, reactor position 3
   (2) TiAl (50:50), 1800×200 mm, reactor position 6 (opposite)

### Deposition Parameters

Average power: 12 kW (per target)
Bias potential: DC, 90 V
Peak power: Target (1): 130 kW; target (2): 140 kW
Peak current: Target (1): 160 A; target (2): 170 A
Frequency: Target (1): 110 Hz; target (2): 100 Hz
Reactive gas: 180 sccm N₂, pressure regulated, 0.53 Pa (500 sccm Ar)
Pulse file: 60

The values given are average values since the plasma conditions change constantly as the substrate table is moved.

The Vickers hardness of the layer sequence of the bonding layer deposited in step 2 was 3000 HV and the E modulus was 480 GPa.

The Vickers hardness of the Ti_{0.5}Al_{0.5}N layer deposited in step 1 at a bias potential of 70 V was measured on layers produced correspondingly having a larger thickness. It was 2900 HV and the E modulus was 470 GPa.

Thereby a gradual transition from the hardness of the substrates to the higher hardness of the alternating layer laminate deposited in step 2 was provided.

The anti-wear protective layer deposited in the HIPIMS process had an overall layer thickness of 2.7 μm and consisted of about 760 TiAlN individual layers having alternately different compositions Ti_{0.5}Al_{0.5}N and Ti_{0.33}Al_{0.67}N (corresponding to the compositions of the targets used). The individual layers of the anti-wear protective layer thus had a thickness of about 3.5 nm, each. The Vickers hardness of the anti-wear protective layer was 3300 HV and the E modulus was 480 GPa.

### Example 3

In this example, the same substrate has been used as in example 1. The multi-layer bonding layer was deposited as in example 2.

For the multi-layer anti-wear protective layer at first a Ti_{0.4}Al_{0.6}N layer having a thickness of about 10 nm was deposited in a first step 1, in a second step 2 a sequence of layers of about 8 individual layers of TiAlN (individual layer thickness about 20 nm) having alternately different compositions Ti_{0.33}Al_{0.67}N and Ti_{0.4}Al_{0.6}N and having a thickness of about 0.16 μm was deposited, and in a third step 3 a sequence of layers of about 24 individual layers of TiAlN (individual layer thickness about 80 nm) having alternately different compositions Ti_{0.33}Al_{0.67}N and Ti_{0.4}Al_{0.6}N and having a thickness of about 1.9 μm was deposited. Finally, a decorative layer having a thickness of 80 nm was applied in the HIPIMS process.

### Anti-Wear Protective Layer (Multi-Layer):

Process: HIPIMS

### Step 1

Target: TiAlN (40:60), 1800×200 mm, reactor position 6

### Deposition Parameters

Average power: 12 kW
Bias potential: DC, 150 V
Peak power: 140 kW
Peak current: 170 A
Frequency: 100 Hz
Reactive gas: 220 sccm N₂, corresponds to about 0.54 Pa (at 500 sccm Ar)
Pulse file: 60

### Step 2

Targets: (1) TiAl (33:67), 1800×200 mm, reactor position 3
   (2) TiAl (40:60), 1800×200 mm, reactor position 6 (opposite)

### Deposition Parameters

Average power: 115 kW (per target)
Bias potential: DC, 100 V
Peak power: Target (1): 135 kW; target (2): 140 kW
Peak current: Target (1): 220 A; target (2): 220 A
Frequency: Target (1): 100-120 Hz; target (2): 90-110 Hz
Reactive gas: N₂, pressure regulated 0.53 Pa (at 500 sccm Ar)
Pulse file: 60

### Step 3

Targets: (1) TiAl (33:67), 1800×200 mm, reactor position 3
(2) TiAl (40:60), 1800×200 mm, reactor position 6 (opposite)

### Deposition Parameters

Average power: 15 kW (per target)
Bias potential: DC, 100 V
Peak power: Target (1): 135 kW; target (2): 140 kW
Peak current: Target (1) 170 A; target (2): 170 A
Frequency: Target (1): 140 Hz; target (2): 125 Hz
Reactive gas: N₂, pressure regulated 0.53 Pa (at 500 sccm Ar)
Pulse file: 60

### Decorative Layer

Target: TiAl (33:67), 1800×200 mm, Reactor Position 3

### Deposition Parameters

Average power: 12 kW
Bias potential: DC, 100 V
Peak power: 135 kW;
Peak current: 170 A;
Frequency: 110 Hz;
Reactive gas: Flow 220 sccm N₂, corresponds to about 0.54 Pa (at 500 sccm Ar)
Pulse file: 60

The hardness of the multi-layer anti-wear protective layer deposited in the HIPIMS process was 3700 HV and the E modulus was 510 GPa.

### Comparative Example 1

In this comparative example, a single-layer anti-wear protective layer of TiAlN was deposited by means of HIPIMS on the same substrate as in example 1.

### Anti-Wear Protective Layer:

Process: HIPIMS
Targets: 2×TiAl (33:67), 1800×200 mm, reactor positions 3 and 6

### Deposition Parameters

Average power: 12 kW (per target)
Bias potential: DC, 100 V
Peak power: 130 kW
Peak current: 160 A
Frequency: 110 Hz
Pulse file: 60

The values given are average values since the plasma conditions constantly change as the substrate table is moved.

The single-layer TiAlN layer deposited in the HIPIMS process had an overall layer thickness of 2.2 μm and the composition Ti_{0.33}Al_{0.67}N (corresponding to the compositions of the targets used). The Vickers hardness of the anti-wear protective layer was 3300 HV and the E modulus was 480 GPa. The HIPIMS layer exhibited a very low surface roughness but also low service lives due to a poor adhesion on the substrate.

### Comparative Example 2

In this comparative example, a single-layer bonding layer of TiAlN having a thickness of 0.6 μm was at first applied by means of arc PVD and a single-layer TiAlN anti-wear protective layer having a thickness of 2 μm was deposited above by means of HIPIMS as in comparative example 1.

### Bonding Layer:

Process: arc PVD
Targets: TiAl (50:50), 100 mm diameter, reactor position 2

### Deposition Parameters

Vaporizer current: 140 A
Center magnet polarity north front
Total pressure: Gradient from 4 to 10 Pa N₂ over 3 min
Bias potential: DC, 100 V

### Anti-Wear Protective Layer:

Process: HIPIMS
Targets: TiAl (33:67), 1800×200 mm, reactor positions 3 and 6 (opposite)

### Deposition Parameters

Average power: 12 kW (per target)
Bias potential: DC, 100 V
Peak power: 130 kW
Peak current: 160 A
Frequency: 110 Hz
Pulse file: 60

The values given are average values since the plasma conditions change constantly as the substrate table is moved.

The Vickers hardness of the bonding layer was 2400 HV and the E modulus was 450 GPa. The single-layer TiAlN layer deposited in the HIPIMS process corresponded to that according to comparative example 1. The coating according to comparative example 2 had a surface roughness that is comparable to the one in the coatings according to the invention, however, having significantly shorter service lives.

### Comparative Example 3

In this comparative example, a multi-layer sequence of layers having a thickness of about 2.5 μm, consisting of about 500 TiAlN individual layers (individual layer thickness about 5 nm) having alternately different compositions Ti_{0.5}Al_{0.5}N and Ti_{0.33}Al_{0.67}N was deposited by means of arc PVD, however, not having any further layers on top. In contrast to the examples and comparative examples described above, a facility designed exclusively for cathodic vacuum arc evaporation (arc PVD), Innova (Balzers, Balzers, Liechtenstein), was used.

### Layer:

Process: arc PVD
Targets: (1) TiAl (50:50) supply Magi 0, 160 mm diameter, reactor positions 1, 2, 3, 6
   (2) TiAl (33:67), supply Mag6, 160 mm diameter, reactor positions 4, 5

### Deposition Parameters

Vaporizer current: 160 A, each
Total pressure: 4 Pa N₂
Bias potential: DC, 60 V

The Vickers hardness of the multi-layer layer was 3200 HV and the E modulus was 460 GPa. The surface roughness of the layer was very high.

1. A tool comprising:
a substrate selected from a hard metal, cermet, ceramic, steel or high-speed steel; and
a multi-layer coating disposed on the substrate via a PVD method and having a total thickness of 1 μm to 20 μm, wherein the multi-layer coating includes a bonding layer and an anti-wear protective layer deposited directly onto the bonding layer, wherein the bonding layer is deposited by cathodic vacuum arc vapor deposition (arc PVD) and has a multi-layer design, wherein layers of the bonding layer which are arranged directly one over the other and have different compositions, and wherein the multiple layers of the bonding layer are each formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof, and wherein the anti-wear protective layer is deposited by high-power impulse magnetron sputtering (HIPIMS) and has a single-layer or multi-layer design, wherein the one or more layers of the anti-wear protective layer are each formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof.

2. The tool according to claim 1, wherein the layers of the bonding layer are each formed from nitrides or carbonitrides of at least two different metals selected from Ti, Al, Si, and Cr.

3. The tool according to claim 1, wherein the multi-layer bonding layer has at least 4 layers arranged one over the other.

4. The tool according to claim 1, wherein within the multi-layer bonding layer the Vickers hardness increases perpendicular to a surface of the substrate in a direction from the substrate to the anti-wear protective layer, and the Vickers hardnesses within the multi-layer bonding layer are in the range of from 1800 HV to 3500 HV.

5. The tool according to claim 1, wherein within the multi-layer bonding layer the modulus of elasticity increases perpendicular to a surface of the substrate in a direction from the substrate to the anti-wear protective layer, and values for the modulus of elasticity within the multi-layer bonding layer are within a range of from 380 GPa to 550 GPa.

6. The tool according to claim 1, wherein the multi-layer bonding layer perpendicular to a surface of the substrate has a thickness in the range of from 0.01 μm to 1 μm, and/or the single-layer or multi-layer anti-wear protective layer has a thickness in the range of from 0.4 μm to 20 μm.

7. The tool according to claim 1, wherein a ratio of the thickness of the single-layer or multi-layer anti-wear protective layer to the thickness of the multi-layer bonding layer is at least 2.0.

8. The tool according to claim 1, wherein the layers of the multi-layer bonding layer comprise alternating layers of titanium aluminum nitride having different compositions, wherein layers of a ratio of Ti:Al of (30 to 36):(70 to 64) alternate with layers having a ratio of Ti:Al of (40 to 60):(60 to 40).

9. The tool according to claim 1, wherein the anti-wear protective coating is multi-layered and has at least 2, 4 or 10 layers arranged one over the other and at most 50, 100 or 300 layers arranged one over the other.

10. The tool according to claim 1, wherein at least one further hard material layer is provided between the substrate and the bonding layer, preferably of TiN or metallic Ti, and/or that at least one further hard material layer is provided on top of the anti-wear protective coating.

11. A process for the production of a coated tool comprising the steps of coating a base body of hard metal, cermet, ceramic, steel or high-speed steel with a multi-layer coating having an overall thickness of 1 μm to 20 μm, by a PVD process, wherein the multi-layer coating comprises a bonding layer and an anti-wear protective layer deposited directly on top of the bonding layer, wherein the bonding layer is deposited by a reactive or non-reactive cathodic vacuum arc vapor deposition to have a multi-layer design, wherein two layers of the bonding layer being each arranged directly one over the other have different compositions, and wherein the multiple layers of the bonding layer are formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof, and wherein the anti-wear protective layer is deposited by means of high-power impulse magnetron sputtering to have a single-layer or multi-layer design, wherein the one or more layers of the anti-wear protective layer are each formed from carbides, nitrides, oxides, carbonitrides, oxicarbides, carboxinitrides of at least two different metals selected from Ti, V, Cr, Zr, Nb, Mo, Ru, Hf, Ta, W, Al, Si, Y, Li and B, and solid solutions thereof.

12. The process according to claim 11, wherein the layers of the bonding layer are each formed from nitrides or carbonitrides of at least two different metals selected from Ti, Al, Si, and Cr.

13. The process according to claim 12, wherein the multi-layer bonding layer has at least 4 layers arranged one over the other.

14. The process according to claim 11, wherein deposition parameters for the deposition of the multi-layer bonding layer are varied such that within the multi-layer bonding layer the Vickers hardness increases perpendicular from a surface of the substrate in the direction from the substrate to the anti-wear protective layer, and the Vickers hardnesses within the multi-layer bonding layer are within the range of from 1800 HV to 3500 HV, wherein the deposition parameters to be varied during the deposition of the multi-layer bonding layer includes at least a bias potential.

15. The tool according to claim 2, wherein the layers of the bonding layer are each formed from AlCrN, AlCrSiN, TiAlN, TiAlSiN, and TiSiN.

16. The tool according to claim 10, wherein the at least one further hard material layer provided on top of the anti-wear protective coating is one or more decorative layers of TiN, TiCN, ZrN.

17. The process according to claim 12, wherein the layers of the bonding layer are each formed from AlCrN, AlCrSiN, TiAlN, TiAlSiN, and TiSiN.
